(19) United States
(12) Patent Application Publication
(10) Pub. No.: US 2015/0171357 A1
(43) Pub. Date: Jun. 18, 2015

(54) MATERIAL FOR ORGANIC ELECTROLUMINESCENCE DEVICE AND ORGANIC ELECTROLUMINESCENCE DEVICE USING THE SAME

(71) Applicant: SAMSUNG DISPLAY CO., LTD., Yongin-City (KR)

(72) Inventor: Ichinori TAKADA, Yokohama (JP)

(21) Appl. No.: 14/564,886

(22) Filed: Dec. 9, 2014

(30) Foreign Application Priority Data
Dec. 16, 2013 (JP) 2013-259563

(51) Int. Cl. H01L 51/50; H01L 51/00

(52) U.S. Cl. CPC H01L 51/5012; H01L 51/0072; H01L 51/0054

(57) ABSTRACT

A compound for an organic EL device and an organic EL device, the compound being represented by the following Formula 1:

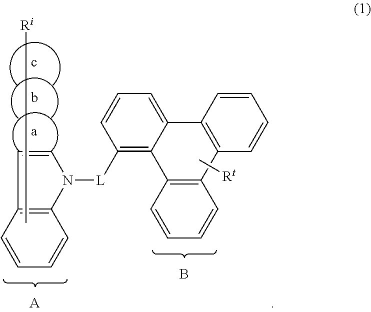

### CROSS-REFERENCE TO RELATED APPLICATION

Japanese Patent Application No. 2013-259563, filed on Dec. 16, 2013, in the Japanese Patent Office, and entitled: “Material for Organic Electroluminescence Device and Organic Electroluminescence Device Using the Same,” is incorporated by reference herein in its entirety.

### BACKGROUND

1. Field

Embodiments relate to a material for an organic electroluminescence device and an organic electroluminescence device using the same.

2. Description of the Related Art

In recent years, organic electroluminescence (EL) displays that are one type of image displays have been actively developed. Unlike a liquid crystal display and the like, the organic EL display is a self-luminescent display that recombines holes and electrons injected from an anode and a cathode in an emission layer to thus emit lights from a light-emitting material including an organic compound of the emission layer, thereby performing display.

An example of an organic electroluminescence device (hereinafter referred to as an organic EL device) may include an organic EL device which includes an anode, a hole transport layer on the anode, an emission layer on the hole transport layer, an electron transport layer on the emission layer, and a cathode on the electron transport layer. Holes injected from the anode may be injected into the emission layer via the hole transport layer. Meanwhile, electrons may be injected from the cathode, and then injected into the emission layer via the electron transport layer. The holes and the electrons injected into the emission layer may be recombined to generate excitons within the emission layer. The organic EL device emits light by using lights generated by the deactivation of radiation of the excitons.

### SUMMARY

Embodiments are directed to an organic electroluminescence device and an organic electroluminescence device using the same.

The embodiments may be realized by providing a compound for an organic electroluminescence (EL) device, the compound being represented by the following Formula 1:

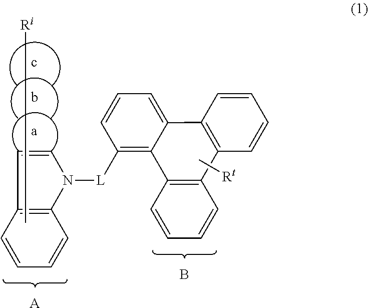

wherein, in Formula 1, A is an indolocarbazole moiety having 0 to 11 of a group R¹, B is a triphenylene moiety having 0 to 11 of a group R^{t}, L is a single bond or a divalent group of an aromatic hydrocarbon or aromatic heterocycle having up to 12 ring carbon atoms, ring a and ring c are each independently an aromatic hydrocarbon ring having 6 ring carbon atoms, and ring b is a heteroaromatic ring having 4 ring carbon atoms and 1 ring nitrogen atom.

A in Formula 1 may be a monovalent group represented by one of the following Formulae (A1), (A2), (A3), (A4), (A5), or (A6):

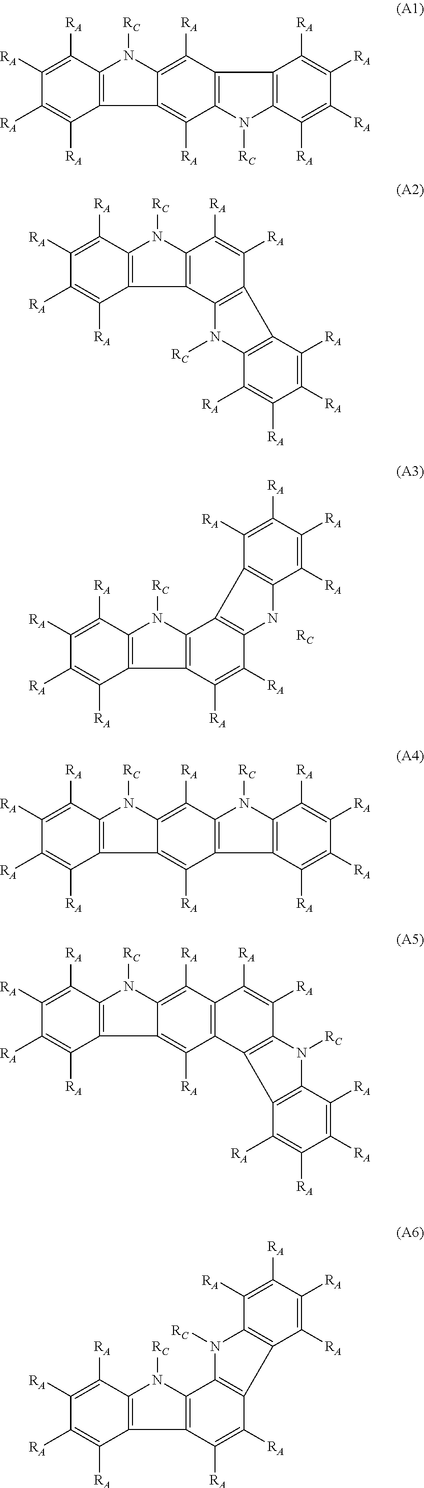

wherein, in Formulae (A1), (A2), (A3), (A4), (A5), and (A6), R_{A} may be a Rⁱ of Formula 1, and each R_{A} may be independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, or an alkylamine group or an arylamine group represented by —N(R_{B})R_{B}, each R_{B} may be independently a saturated or unsaturated hydrocarbon having 1 to 10 carbon atoms, and each R_{C} may be independently R_{A} or a single bond to L.

L in Formula 1 may be a divalent group represented by one of the following Formulae (L1), (L2), (L3), or (L4):

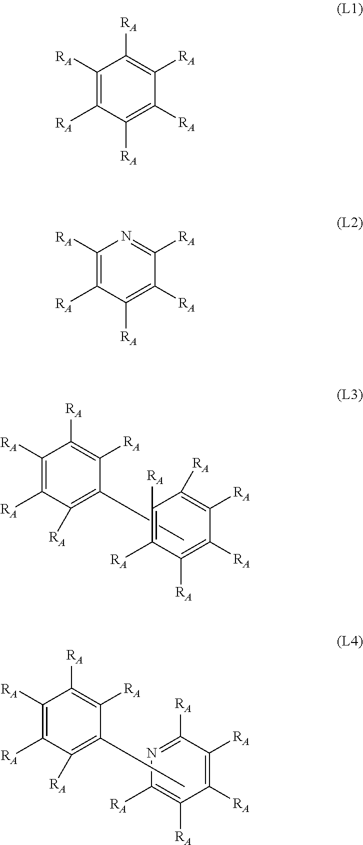

wherein, in Formulae (L1), (L2), (L3), and (L4), each R_{A} may be independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, an alkylamine group or an arylamine group represented by —N(R_{B})R_{B}, or a bond to A or B of Formula 1, and R_{B} may be saturated or unsaturated hydrocarbon having 1 to 10 carbon atoms.

The embodiments may be realized by providing an organic electroluminescence (EL) device including a compound for an organic EL device in at least one of an emission layer or a layer stacked between the emission layer and an anode, the compound for an organic EL device being represented by the following Formula 1:

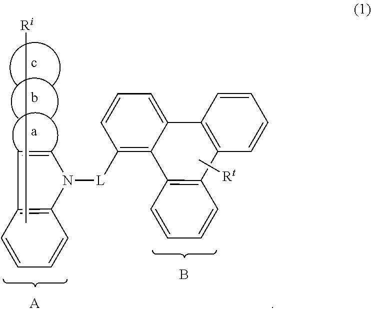

wherein, in Formula 1, A is an indolocarbazole moiety having 0 to 11 of a group Rⁱ, B is a triphenylene moiety having 0 to 11 of a group R^{t}, L is a single bond or a divalent group of an aromatic hydrocarbon or aromatic heterocycle having up to 12 ring carbon atoms, ring a and ring c are each independently an aromatic hydrocarbon ring having 6 ring carbon atoms, and ring b is a heteroaromatic ring having 4 ring carbon atoms and 1 ring nitrogen atom.

A in Formula 1 may be a monovalent group represented by one of the following Formulae (A1), (A2), (A3), (A4), (A5), or (A6):

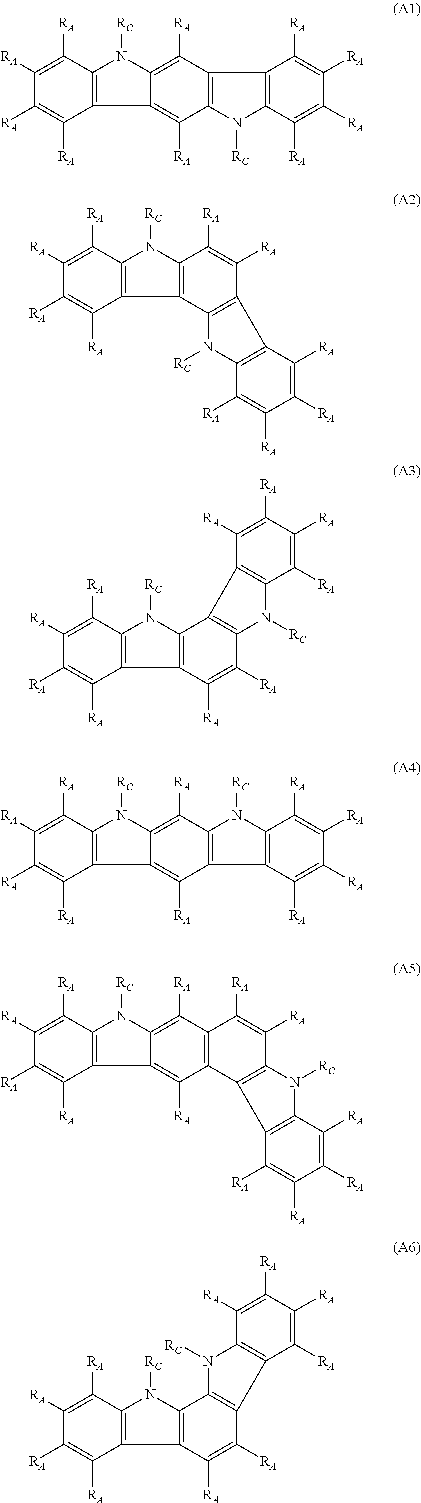

wherein, in Formulae (A1), (A2), (A3), (A4), (A5), and (A6), R_{A} is a Rⁱ of Formula 1, and each R_{A} is independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, or an alkylamine group or an arylamine group represented by —N(R_{B})R_{B}, each R_{B} may be independently a saturated or unsaturated hydrocarbon having 1 to 10 carbon atoms, and each R_{C} may be independently R_{A} or a single bond to L.

L in Formula 1 may be a divalent group represented by one of the following Formulae (L1), (L2), (L3), or (L4):

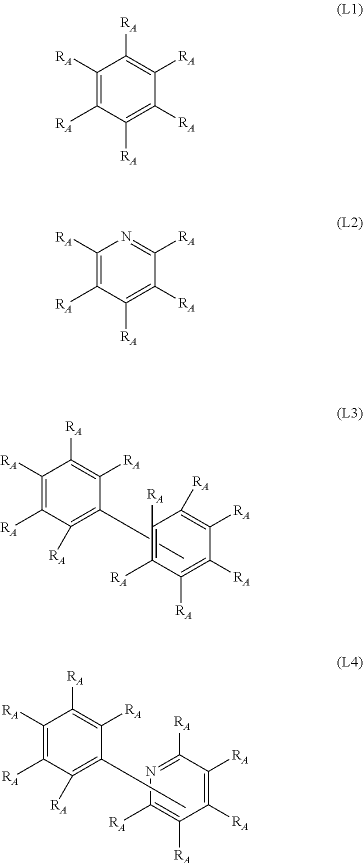

wherein, in Formulae (L1), (L2), (L3), and (L4), each R_{A} may be independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, an alkylamine group or an arylamine group represented by —N(R_{B})R_{B}, or a bond to A or B of Formula 1, and R_{B} may be a saturated or unsaturated hydrocarbon having 1 to 10 carbon atoms.

The compound represented by Formula 1 may be one of the following Compounds 1 to 6:

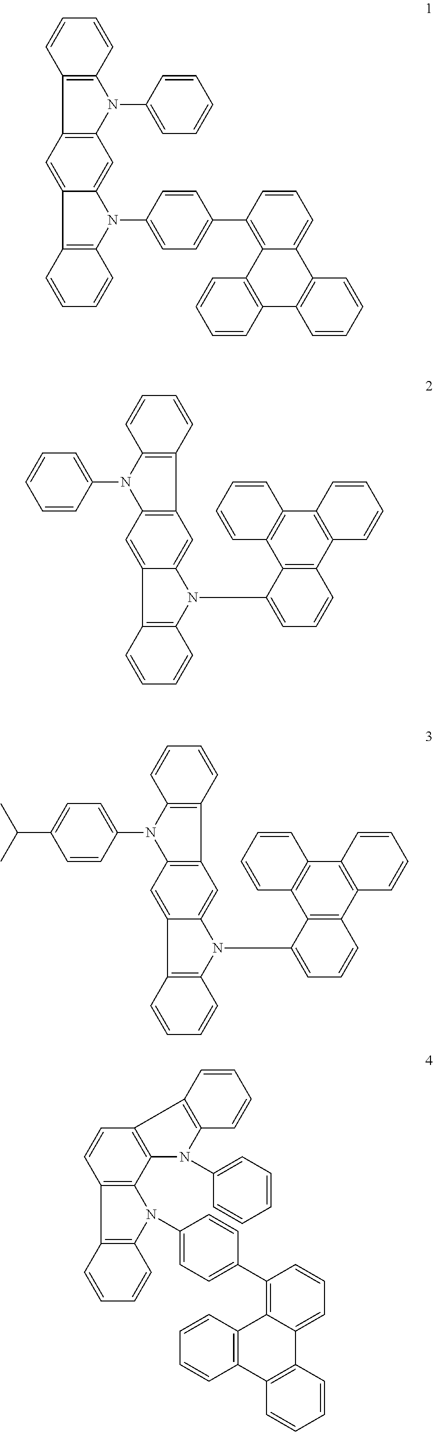

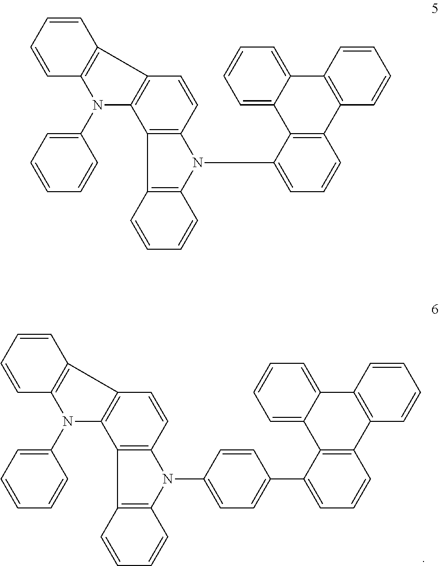 [SMILES: c1ccc(-n2c3ccccc3c3ccc4c(c5ccccc5n4-c4cccc5c6ccccc6c6ccccc6c45)c32)cc1 ; c1ccc(-n2c3ccccc3c3ccc4c(c5ccccc5n4-c4ccc(-c5cccc6c7ccccc7c7ccccc7c56)cc4)c32)cc1]

The compound represented by Formula 1 may be one of the following Compounds 7 to 12:

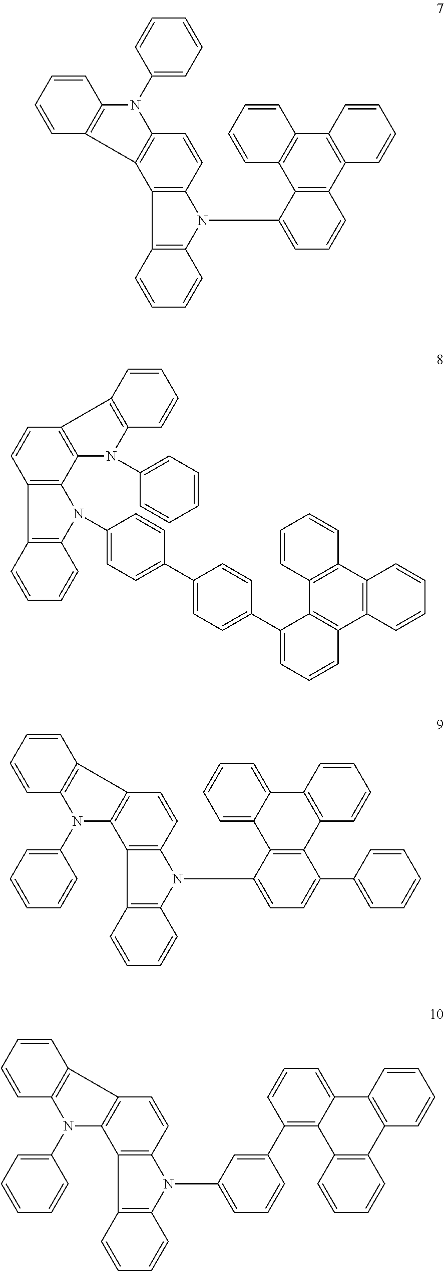 [SMILES: c1ccc(-n2c3ccccc3c3c4c5ccccc5n(-c5cccc6c7ccccc7c7ccccc7c56)c4ccc32)cc1 ; c1ccc(-n2c3ccccc3c3ccc4c5ccccc5n(-c5ccc(-c6ccc(-c7cccc8c9ccccc9c9ccccc9c78)cc6)cc5)c4c32)cc1 ; c1ccc(-c2ccc(-n3c4ccccc4c4c3ccc3c5ccccc5n(-c5ccccc5)c34)c3c4ccccc4c4ccccc4c23)cc1 ; c1ccc(-n2c3ccccc3c3ccc4c(c5ccccc5n4-c4cccc(-c5cccc6c7ccccc7c7ccccc7c56)c4)c32)cc1]

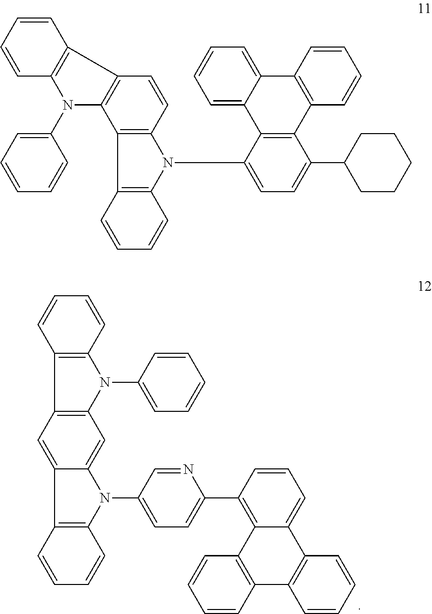 [SMILES: c1ccc(-n2c3ccccc3c3ccc4c(c5ccccc5n4-c4ccc(C5CCCCC5)c5c6ccccc6c6ccccc6c45)c32)cc1 ; c1ccc(-n2c3ccccc3c3cc4c5ccccc5n(-c5ccc(-c6cccc7c8ccccc8c8ccccc8c67)nc5)c4cc32)cc1]

The compound represented by Formula 1 may be one of the following Compounds 13 to 18:

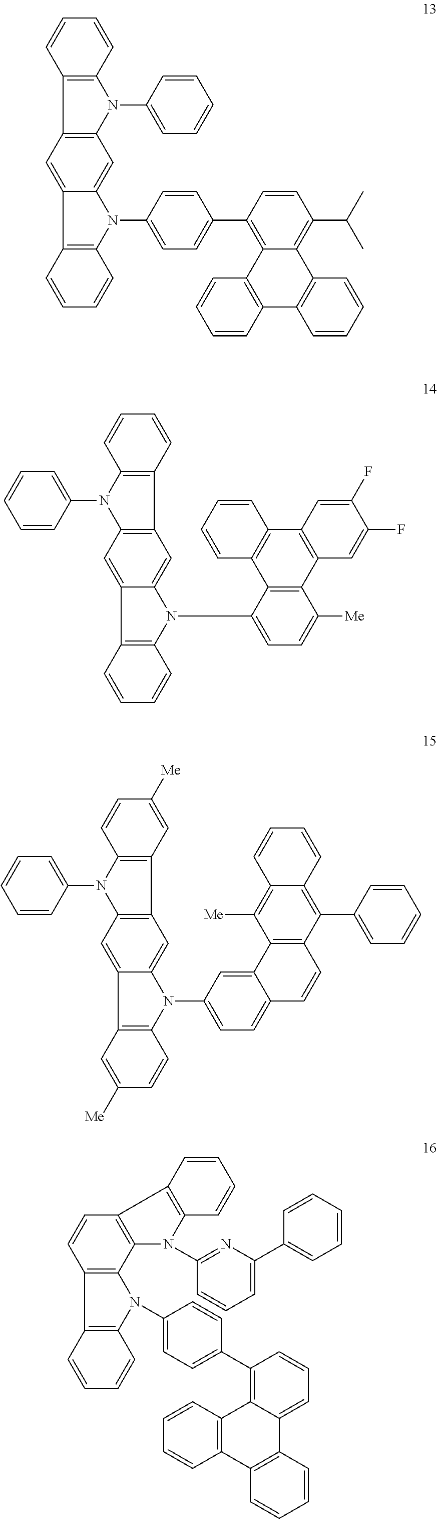 [SMILES: CC(C)c1ccc(-c2ccc(-n3c4ccccc4c4cc5c6ccccc6n(-c6ccccc6)c5cc43)cc2)c2c3ccccc3c3ccccc3c12 ; Cc1ccc(-n2c3ccccc3c3cc4c(cc32)c2ccccc2n4-c2ccccc2)c2c3ccccc3c3cc(F)c(F)cc3c12 ; Cc1ccc2c(c1)c1cc3c(cc1n2-c1ccccc1)c1cc(C)ccc1n3-c1ccc2ccc3c(-c4ccccc4)c4ccccc4c(C)c3c2c1 ; c1ccc(-c2cccc(-n3c4ccccc4c4ccc5c6ccccc6n(-c6ccc(-c7cccc8c9ccccc9c9ccccc9c78)cc6)c5c43)n2)cc1]

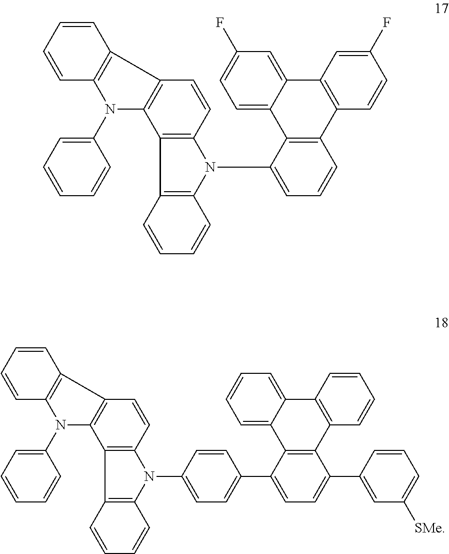 [SMILES: Fc1ccc2c(c1)c1cc(F)ccc1c1c(-n3c4ccccc4c4c3ccc3c5ccccc5n(-c5ccccc5)c34)cccc21 ; CSc1cccc(-c2ccc(-c3ccc(-n4c5ccccc5c5c4ccc4c6ccccc6n(-c6ccccc6)c45)cc3)c3c4ccccc4c4ccccc4c23)c1]

The compound represented by Formula 1 may be one of the following Compounds 19 to 24:

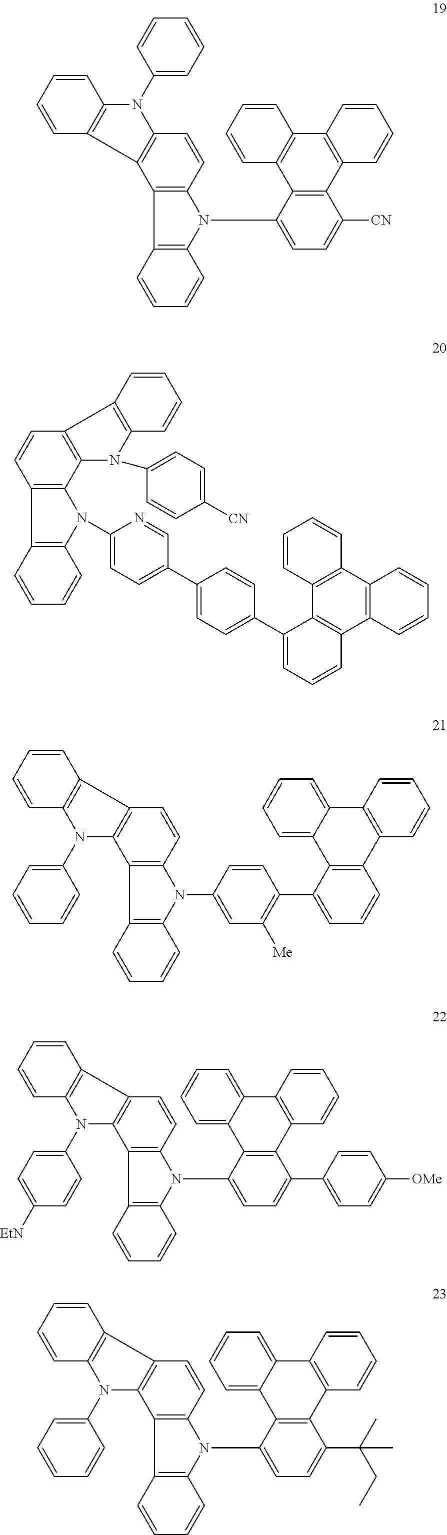

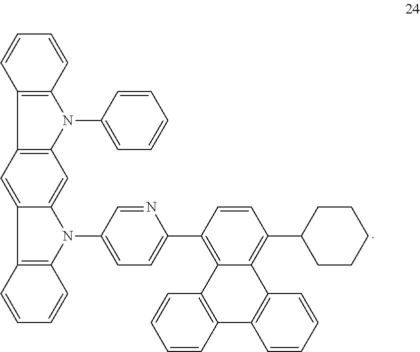 [SMILES: c1ccc(-n2c3ccccc3c3cc4c5ccccc5n(-c5ccc(-c6ccc(C7CCCCC7)c7c8ccccc8c8ccccc8c67)nc5)c4cc32)cc1]

### BRIEF DESCRIPTION OF THE DRAWING

Features will become apparent to those of ordinary skill in the art by describing in detail exemplary embodiments with reference to the attached drawing in which:

FIG. 1 illustrates a schematic diagram of an organic EL device 100 according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

According to an embodiment, hole tolerance and electron tolerance of an organic EL device may be improved, and the high efficiency and the long life of an organic EL device may be realized by using a material obtained by combining an indolocarbazole moiety having high hole tolerance with a triphenylene moiety having hole tolerance and electron tolerance via a connecting group. A compound introducing the indolocarbazole moiety and the triphenylene moiety via the connecting group may lengthen life. For example, remarkably high efficiency and long life may be realized by combining a carbon at position 1 of the triphenylene moiety with a nitrogen of the indolocarbazole moiety via the connecting group.

The material for an organic EL device according to an embodiment may include a compound for an organic EL device. In an implementation, the compound may be represented by the following Formula 1. For example, in the compound represented by Formula 1, an indolocarbazole moiety may be bound to a triphenylene moiety via a connecting group.

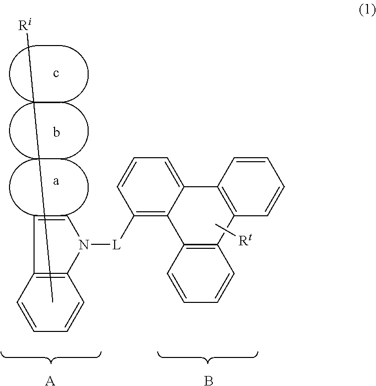

In Formula 1, A may be or may include an indolocarbazole moiety. For example, the indolocarbazole moiety may include a substituent or group Rⁱ thereon. B may be or may include a triphenylene moiety. For example, the triphenylene moiety may have a substituent or group R^{t}. For example, as shown in Formula 1, one R^{t}, or a plurality of R^{t}s may be bound to the triphenylene moiety at any open position of the rings of the triphenylene moiety.

L may be a single bond or a divalent group of an aromatic hydrocarbon or aromatic heterocycle having up to 12, e.g., 1 to 12, ring carbon atoms. Ring a and ring c may each independently be an aromatic hydrocarbon ring having 6 ring carbon atoms, and ring b may be a heteroaromatic ring having 4 ring carbon atoms and 1 ring nitrogen atom. For example, rings a, b, and c may for a fused ring structure. Rⁱ and R^{t} may each independently be substituents or groups on A or B of Formula 1. In an implementation, 0 to 11 Rⁱs may be included on the indolocarbazole moiety A. In an implementation, 0 to 11 R^{t}s may be included on the triphenylene moiety B. For example, when a number of Rⁱ or R^{t} is 0, only a hydrogen may be present on A or B.

In an implementation, the substituent or group Rⁱ and/or R^{t} may include, e.g., hydrogen, a methyl group, an ethyl group, a propyl group, an isopropyl group, a n-butyl group, an s-butyl group, an isobutyl group, a t-butyl group, a n-pentyl group, a n-hexyl group, a n-heptyl group, a n-octyl group, a cyclopropyl group, a cyclobutyl group, a cyclopentyl group, a cyclohexyl group, a 4-methylcyclohexyl group, a 1-adamantly group, a 2-adamantyl group, a 1-norbonyl group, a 2-norbonyl group, a dimethylallyl group, a geranyl group, a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, a 9,9-dimethylfluorenyl group, etc.

In an implementation, A in the above Formula 1 may be a monovalent group derived an aromatic hydrocarbon. For example, A may be a monovalent group represented by one of the following Formulae (A1), (A2), (A3), (A4), (A5), or (A6).

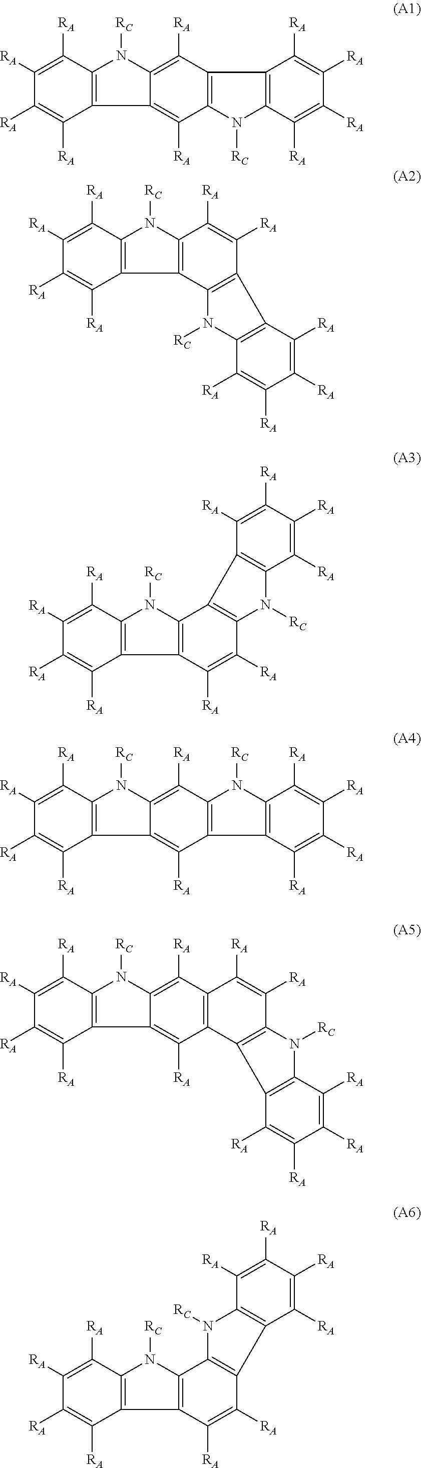

In the above Formulae (A1), (A2), (A3), (A4), (A5), and (A6), R_{A} may correspond with or be Rⁱ of Formula 1. For example, each R_{A} may independently be hydrogen, deuterium, a halogen atom, a nitrile group, a saturated or unsaturated hydrocarbon group having at most 30, e.g., 1 to 30, carbon atoms, an alkoxy group represented by —OR_{B}, an alkylthio group represented by —SR_{B}, or an alkylamine group or an arylamine group represented by —N(R_{B})R_{B}. R_{B} may be a saturated or unsaturated hydrocarbon having at most 10, e.g., 1 to 10, carbon atoms. In an implementation, R^{t} of Formula 1 may be defined the same as Rⁱ and/or R_{A}, above. In an implementation, R_{C} may be a group that is defined the same as R_{A}, or may be a bond to L of Formula 1.

In an implementation, the saturated or unsaturated hydrocarbon group having 1 to 30 carbon atoms of R_{A} may include, e.g., a methyl group, an ethyl group, a propyl group, an isopropyl group, a n-butyl group, an s-butyl group, an isobutyl group, a t-butyl group, a n-pentyl group, a n-hexyl group, a n-heptyl group, a n-octyl group, a cyclopropyl group, a cyclobutyl group, a cyclopentyl group, a cyclohexyl group, a 4-methylcyclohexyl group, a 1-adamantly group, a 2-adamantyl group, a 1-norbonyl group, a 2-norbonyl group, a dimethylallyl group, a geranyl group, a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4% methylbiphenylyl group, a 4″-t-butyl-p-terphenyl-4-yl group, a fluoranthenyl group, a fluorenyl group, a 9,9-dimethylfluorenyl group, etc.

In an implementation, L in the above Formula 1 may be a single bond or a divalent group derived from an aromatic hydrocarbon or an aromatic heterocycle. For example, L may be a divalent group represented by one of the following Formulae (L1), (L2), (L3), or (L4).

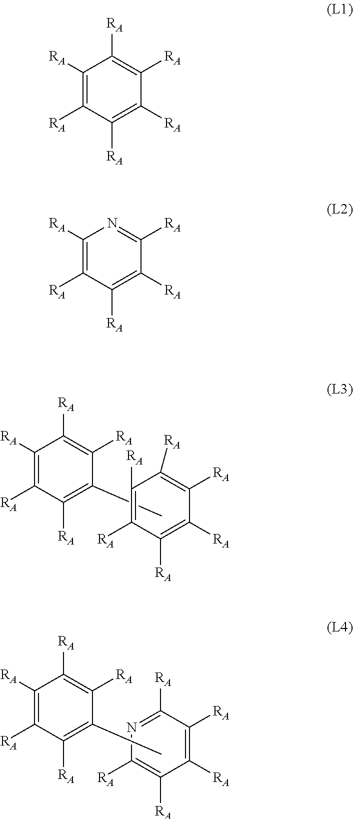

In Formulae (L1), (L2), (L3), and (L4), each R_{A} is independently hydrogen, deuterium, a halogen atom, a nitrile group, a saturated or unsaturated hydrocarbon group having at most 30, e.g., 1 to 30, carbon atoms, an alkoxy group represented by —OR_{B}, an alkylthio group represented by —SR_{B}, an alkylamine group or an arylamine group represented by —N(R_{B})R_{B}, or a bond to A or B of Formula 1. In an implementation, R_{B} may be a saturated or unsaturated hydrocarbon having at most 10, e.g., 1 to 10, carbon atoms. Examples of the saturated or unsaturated hydrocarbon group having 1 to 30 carbon of R_{A} may be the same as have been described above.

The material for an organic EL device according to an embodiment may include the compound having the above-described structure. In an implementation, the compound may have, e.g., a molecular weight of less than or equal to about 800, for an appropriate application of a vacuum deposition process.

The material for an organic EL device according to an embodiment may include the compound having an A-L-B structure in which A denotes a heteroaryl group, B denotes an aryl group, and L denotes a single bond or a connecting group. For the use of the material in an emission layer or an organic thin layer between an emission layer and an anode, tolerance may be required with respect to electrons that have arrived at the emission layer or that have passed through the emission layer among electrons injected from a cathode in the organic EL device. In addition, in the case that the material is used in the organic thin layer between the emission layer and the anode, the trapping operation of excited energy from the emission layer in the emission layer may be required. Thus, bipolar properties may be necessary for an entire molecule, and the material according to an embodiment may be characterized in having good separation between the highest occupied molecular orbital (HOMO) and the lowest unoccupied molecular orbital (LUMO).

In the material for an organic EL device according to an embodiment, an indolocarbazole moiety having high hole tolerance and a triphenylene moiety having hole tolerance and electron tolerance may be combined or bound via a connecting group. The hole tolerance and the electron tolerance of the organic EL device may be improved and thus, the high efficiency and the long life of the organic EL device may be attained. For example, the indolocarbazole moiety may be combined with the triphenylene moiety at position 1, via the connecting group, a dihedral angle of a molecule may be increased, and the long life of the organic EL device may be realized.

The material for an organic EL device according to an embodiment may include one of the following Compounds 1 to 6.

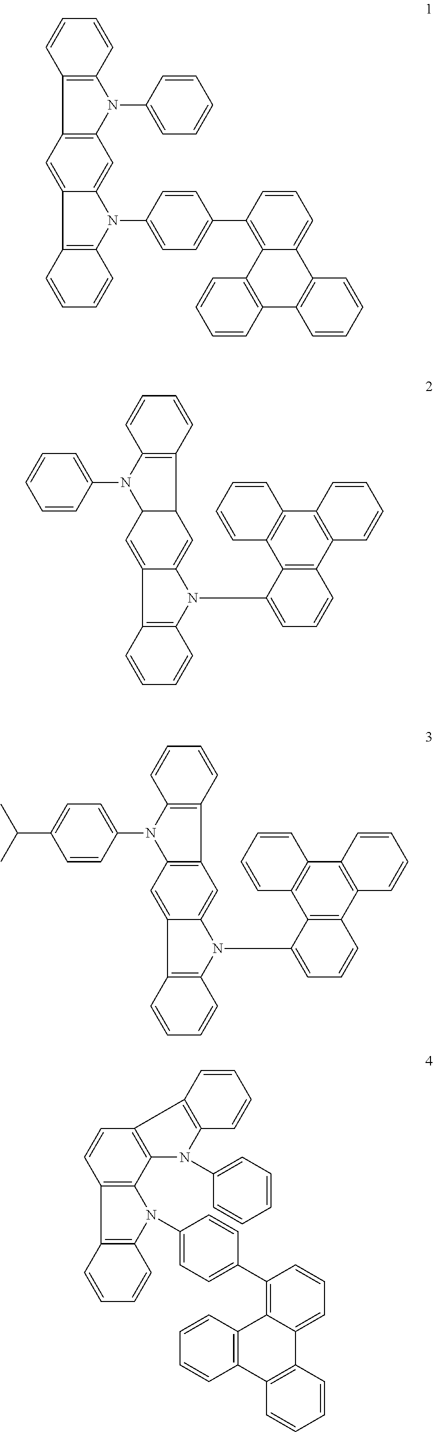

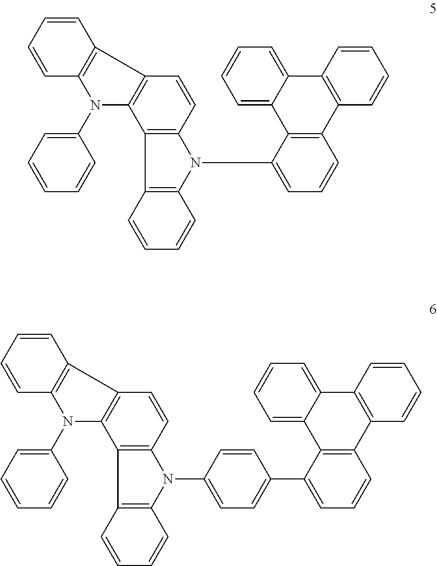 [SMILES: c1ccc(-n2c3ccccc3c3ccc4c(c5ccccc5n4-c4cccc5c6ccccc6c6ccccc6c45)c32)cc1 ; c1ccc(-n2c3ccccc3c3ccc4c(c5ccccc5n4-c4ccc(-c5cccc6c7ccccc7c7ccccc7c56)cc4)c32)cc1]

The material for an organic EL device according to an embodiment may include one of the following Compounds 7 to 12.

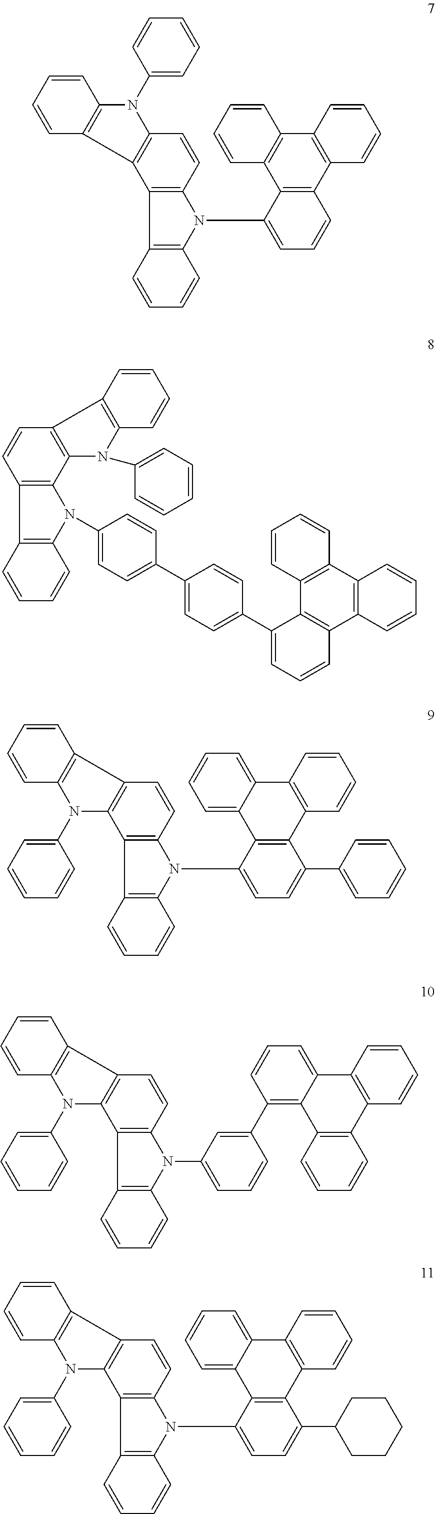 [SMILES: c1ccc(-n2c3ccccc3c3c4c5ccccc5n(-c5cccc6c7ccccc7c7ccccc7c56)c4ccc32)cc1 ; c1ccc(-n2c3ccccc3c3ccc4c5ccccc5n(-c5ccc(-c6ccc(-c7cccc8c9ccccc9c9ccccc9c78)cc6)cc5)c4c32)cc1 ; c1ccc(-c2ccc(-n3c4ccccc4c4c3ccc3c5ccccc5n(-c5ccccc5)c34)c3c4ccccc4c4ccccc4c23)cc1 ; c1ccc(-n2c3ccccc3c3ccc4c(c5ccccc5n4-c4cccc(-c5cccc6c7ccccc7c7ccccc7c56)c4)c32)cc1 ; c1ccc(-n2c3ccccc3c3ccc4c(c5ccccc5n4-c4ccc(C5CCCCC5)c5c6ccccc6c6ccccc6c45)c32)cc1]

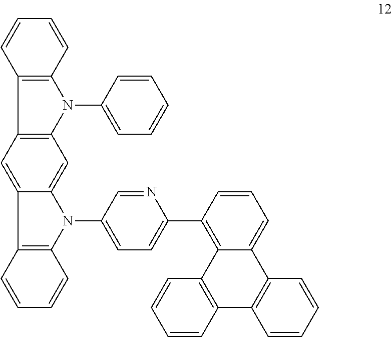 [SMILES: c1ccc(-n2c3ccccc3c3cc4c5ccccc5n(-c5ccc(-c6cccc7c8ccccc8c8ccccc8c67)nc5)c4cc32)cc1]

The material for an organic EL device according to an embodiment may include one of the following Compounds 13 to 18.

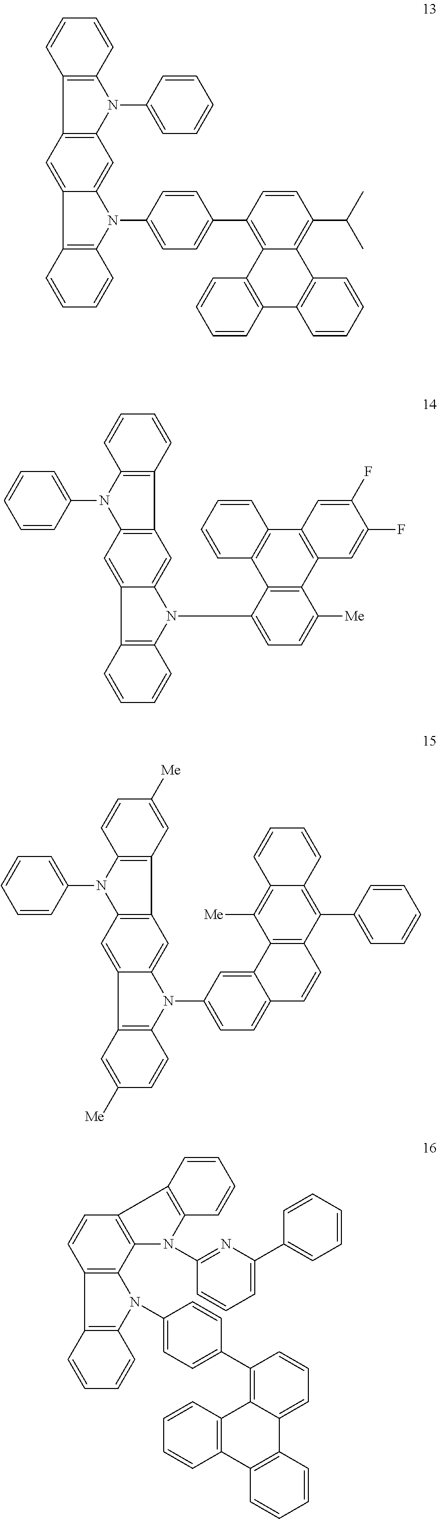 [SMILES: CC(C)c1ccc(-c2ccc(-n3c4ccccc4c4cc5c6ccccc6n(-c6ccccc6)c5cc43)cc2)c2c3ccccc3c3ccccc3c12 ; Cc1ccc(-n2c3ccccc3c3cc4c(cc32)c2ccccc2n4-c2ccccc2)c2c3ccccc3c3cc(F)c(F)cc3c12 ; Cc1ccc2c(c1)c1cc3c(cc1n2-c1ccccc1)c1cc(C)ccc1n3-c1ccc2ccc3c(-c4ccccc4)c4ccccc4c(C)c3c2c1 ; c1ccc(-c2cccc(-n3c4ccccc4c4ccc5c6ccccc6n(-c6ccc(-c7cccc8c9ccccc9c9ccccc9c78)cc6)c5c43)n2)cc1]

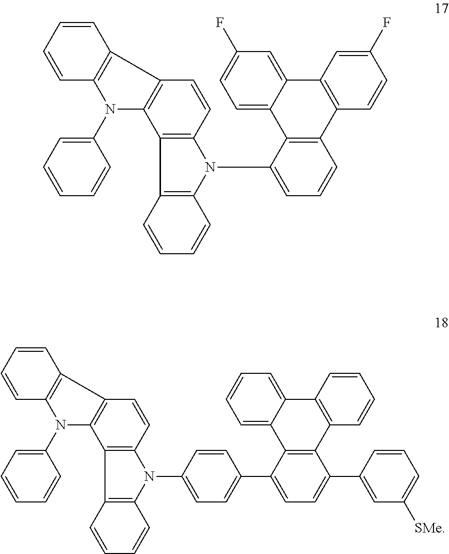 [SMILES: Fc1ccc2c(c1)c1cc(F)ccc1c1c(-n3c4ccccc4c4c3ccc3c5ccccc5n(-c5ccccc5)c34)cccc21 ; CSc1cccc(-c2ccc(-c3ccc(-n4c5ccccc5c5c4ccc4c6ccccc6n(-c6ccccc6)c45)cc3)c3c4ccccc4c4ccccc4c23)c1]

The material for an organic EL device according to an embodiment may include one of the following Compounds 19 to 24.

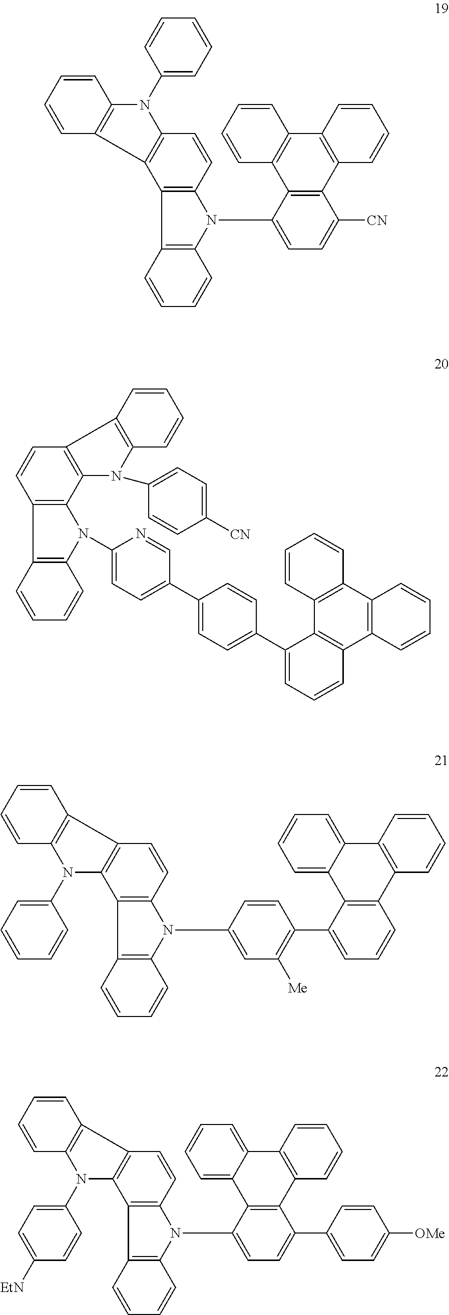

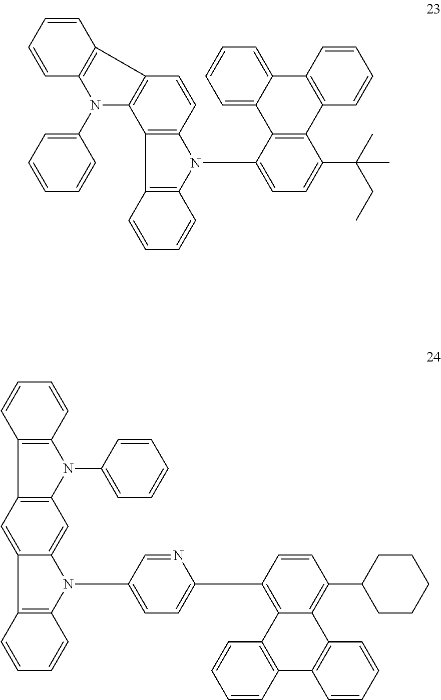 [SMILES: CCC(C)(C)c1ccc(-n2c3ccccc3c3c2ccc2c4ccccc4n(-c4ccccc4)c23)c2c3ccccc3c3ccccc3c12 ; c1ccc(-n2c3ccccc3c3cc4c5ccccc5n(-c5ccc(Cc6ccc(C7CCCCC7)c7c8ccccc8c8ccccc8c67)nc5)c4cc32)cc1]

The material for an organic EL device according to an embodiment may be appropriately used in an emission layer. In an implementation, the material for an organic EL device may be used in a layer stacked between the emission layer and an anode. By using the material, hole transport properties may be improved, and an organic EL device driven at a low voltage and having high efficiency may be manufactured.

(Organic EL device)

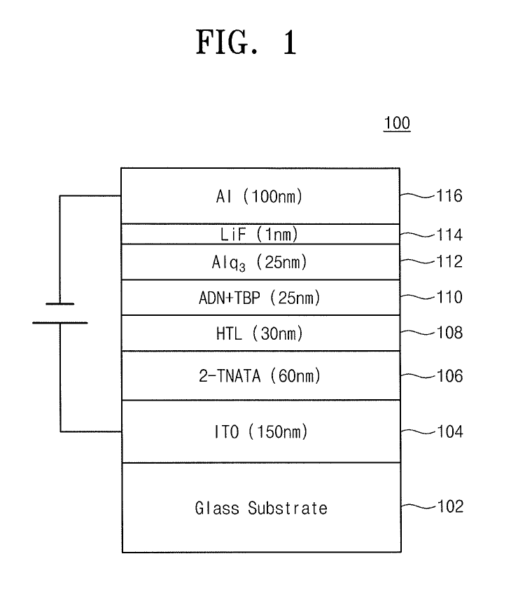

An organic EL device including the material for an organic EL device according to an embodiment will be explained. FIG. 1 illustrates a schematic diagram of the configuration of an organic EL device 100 according to an embodiment. The organic EL device 100 may include, e.g., a substrate 102, an anode 104, a hole injection layer 106, a hole transport layer 108, an emission layer 110, an electron transport layer 112, an electron injection layer 114, and a cathode 116. In an implementation, the material for an organic EL device according to an embodiment may be used or included in the emission layer. In an implementation, the material for an organic EL device according to an embodiment may be used or included in a layer stacked between the emission layer and the anode.

For example, the material for an organic EL device according to an embodiment may be included in the hole transport layer 108 and will be explained below. The substrate 102 may be a transparent glass substrate, a semiconductor substrate formed by using silicon, etc., or a flexible substrate of a resin, etc. The anode 104 may be disposed on the substrate 102 and may be formed using indium tin oxide (ITO), indium zinc oxide (IZO), etc. The hole injection layer 106 may be disposed on the anode 104 and may include, for example, 4,4′,4″-tris[2-naphthyl)(phenyl)amino]triphenylamine (2-TNATA), N,N,N′,N′-tetrakis(3-methylphenyl)-3,3′-dimethylbenzidine (HMTPD), dipyrazino[2,3-f:2′,3′-h]quinoxaline-2,3,6,7,10,11-hexacarbonitrle (HAT(CN)₆), etc. The hole transport layer 108 may be disposed on the hole injection layer 106 and may be formed using the material for an organic EL device according to an embodiment. The emission layer 110 may be disposed on the hole transport layer 108 and may be formed using the material for an organic EL device according to an embodiment. In an implementation, the emission layer 110 may be formed using, e.g., a host material including 9,10-di(2-naphthyl)anthracene (ADN) doped with 2,5,8,11-tetra-t-butylperylene (TBP). The electron transport layer 112 may be disposed on the emission layer 110 and may be formed using, e.g., a material including tris(8-hydroxyquinolinato)aluminum (Alq₃). The electron injection layer 114 may be disposed on the electron transport layer 112 and may be formed using, e.g., a material that includes lithium fluoride (LiF). The cathode 116 may be disposed on the electron injection layer 114 and may be formed using a metal such as A1 or a transparent material such as ITO, IZO, etc. The above-described thin layers may be formed by selecting an appropriate layer forming method such as vacuum deposition, sputtering, various coatings, etc.

In the organic EL device 100 according to this embodiment, a hole transport layer realizing driving at a low voltage and high efficiency may be formed by using the material for an organic EL device according to an embodiment. In an implementation, the material for an organic EL device according to an embodiment may be applied or used in an organic EL apparatus of an active matrix using thin film transistors (TFT).

In addition, in the organic EL device 100 according to this embodiment, an organic EL device driven at a low voltage and having high efficiency and long life may be manufactured by using the material for an organic EL device according to an embodiment in the emission layer or the layer stacked between the emission layer and the anode.

### Examples

### Preparation Method

The material for an organic EL device according to an embodiment may be synthesized by, for example, one of the following methods of Type 1 to Type 3 of Reaction Scheme 1.

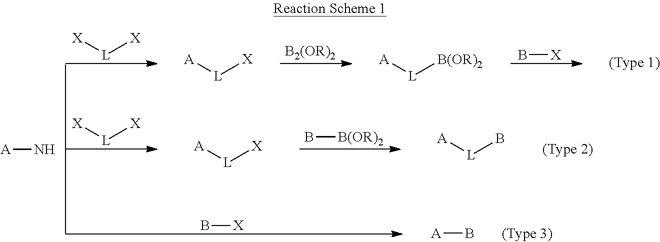

(Synthetic Method of Type 1)

Through an Ullmann reaction of an indolocarbazole compound (A-NH) and a dihalide compound (X-L-X) and the elongation of a connecting group L, an intermediate (A-L-X) may be obtained. The residual halogen of the intermediate (A-L-X) may be (1) treated using diborane (B₂(OR)₂) with a palladium catalyst or (2) lithiated using n-butyllithium, etc. and treated using trisborate to transform into a boronic acid ester (A-L-B(OR)₂). Then, through Suzuki-Miyaura coupling reaction of the boronic acid ester with B halide (B-X), an A-L-B type material may be produced.

(Synthetic Method of Type 2)

The intermediate (A-L-X) may be obtained by the same method described in Type 1. Then, through Suzuki-Miyaura coupling reaction of the boronic acid ester of B (B-B(OR)₂), an A-L-B type material may be produced.

(Synthetic Method of Type 3)

Through an Ullmann reaction or through using a Hartwig reaction type Pd catalyst, a direct reaction of an indolocarbazole compound (A-NH) and B halide (B-X) may be performed to produce a direct A-B type material.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

As an Example, Compound 9 was synthesized by the method of Type 2, as shown in Reaction Scheme 2, below. The synthesized compound was identified by FAB-MS measurement.

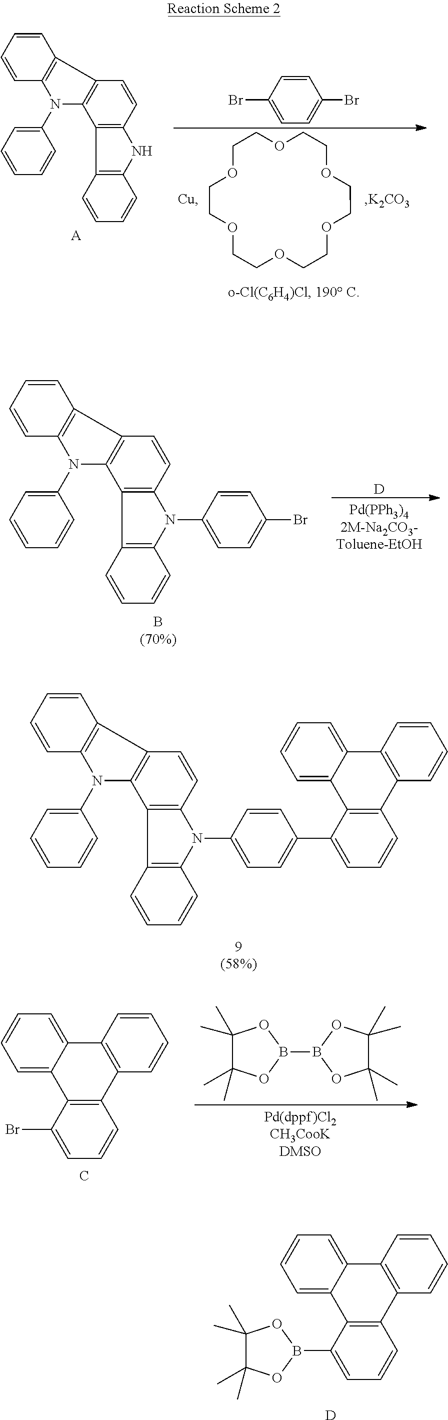

(Synthesis of Bromo Compound B)

Indolocarbazole A (2.00 g, 6.20 mmol), 1,4-dibromobenzene (14.6 g, 62.00 mmol), copper powder (3.15 g, 49.6 mmol), and 18-crown-6 (860 mg, 3.72 mmol) were dissolved in o-dichlorobenzene (20 mL) and stirred at 190° C. for 14 hours. After cooling, the reaction mixture was added into hexane, and the obtained precipitate was filtered. The obtained solid was washed with chloroform, and the washed solution was concentrated. The obtained residue was separated by silica gel chromatography to produce bromo compound B (2.12 g, 4.34 mmol) with a yield of 70%.

(Synthesis of Compound B)

Under an argon atmosphere, 4.70 g of Compound A, 6.24 g of 1-bromo-4-iodobenzene, 7.48 g of copper, 16.3 g of potassium carbonate (K₂CO₃), 2.33 g of 18-crown-6-ether and 47 mL of DMF were added to a 200 mL, three-necked flask, followed by stirring at 190° C. for 10 hours. After cooling in the air, an organic layer was separated, and solvents were distilled. Then, recrystallization was performed using toluene to produce 4.61 g of Compound B as white solid (yield 66%).

(Synthesis of Boronic Acid Pinacol Ester D)

A bromide compound C (3.50 g, 11.6 mmol), bis(pinacolato)diborane (4.40 g, 17.3 mmol), a [1,1-bis(diphenylphosphino)ferrocene]dichloropalladium(II)dichloromethane complex (470 mg, 0.58 mmol) and potassium acetate (3.40 g, 34.9 mmol) were dissolved in dimethyl sulfoxide (100 mL), followed by stirring at 90° C. for 8 hours. Into the reaction mixture, water was added, and extraction with chloroform was performed. An organic layer was washed with saturated brine and dried with magnesium sulfate. The organic layer was concentrated, and the obtained residue was separated by silica gel column chromatography to produce boronic acid pinacol ester D (2.26 g, 6.38 mmol) with yield of 55%.

(Synthesis of Compound 9)

Bromo compound B (1.46 g, 3.00 mmol), boronic acid pinacol ester D (1.17 g, 3.30 mmol) and tetrakis(triphenylphosphine)palladium(0) (170 mg, 0.15 mmol) were added to a mixed solvent of toluene (50 mL)-2 M aqueous sodium carbonate solution (50 mL)-ethanol (50 mL), followed by degassing and heating while refluxing for 8 hours. The obtained precipitate was heated and filtered and subsequently washed with toluene, water, and ethanol to produce Compound 9 (1.05 g, 1.65 mmol) as a nearly white solid with a yield of 55%.

Organic EL devices according to Examples 1 and 2 were manufactured by using Compounds 5 and 6 (manufactured by the above-described manufacturing method) as hole transport materials. In addition, organic EL devices according to Comparative Examples 1 to 3 were manufactured by using the following Compounds R1 to R3 as hole transport materials. Compound R1 was obtained by introducing an indolocarbazole moiety at position 2 of a triphenylene moiety via a connecting group.

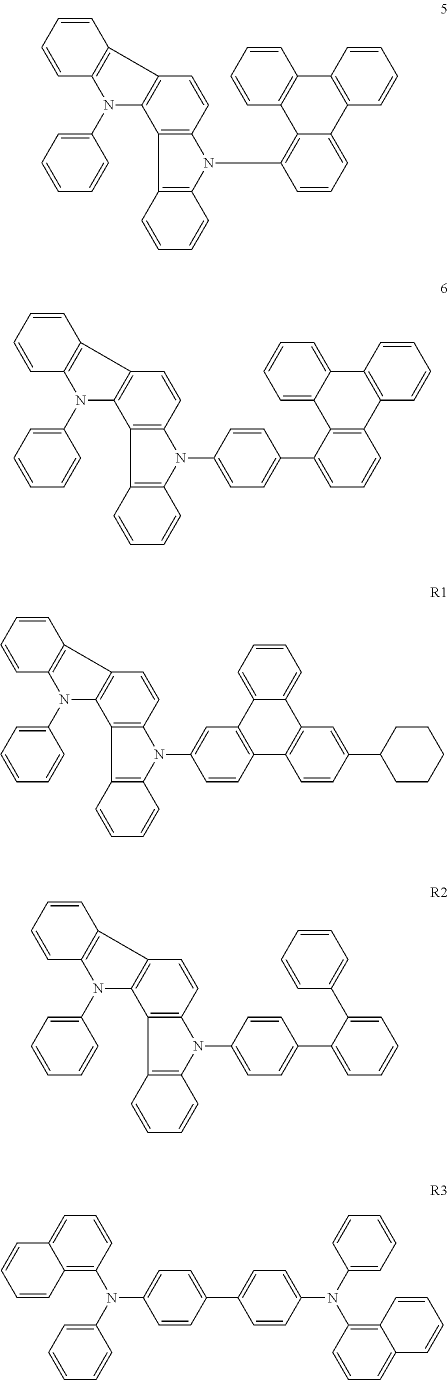 [SMILES: c1ccc(-n2c3ccccc3c3ccc4c(c5ccccc5n4-c4cccc5c6ccccc6c6ccccc6c45)c32)cc1 ; c1ccc(-n2c3ccccc3c3ccc4c(c5ccccc5n4-c4ccc(-c5cccc6c7ccccc7c7ccccc7c56)cc4)c32)cc1 ; c1ccc(-n2c3ccccc3c3ccc4c(c5ccccc5n4-c4ccc5c6ccc(C7CCCCC7)cc6c6ccccc6c5c4)c32)cc1 ; c1ccc(-c2ccccc2-c2ccc(-n3c4ccccc4c4c3ccc3c5ccccc5n(-c5ccccc5)c34)cc2)cc1 ; c1ccc(N(c2ccc(-c3ccc(N(c4ccccc4)c4cccc5ccccc45)cc3)cc2)c2cccc3ccccc23)cc1]

In the Examples and Comparative Examples, the substrate 102 was formed by using a transparent glass substrate, the anode 104 was formed using ITO to a thickness of about 150 nm, the hole injection layer 106 having a thickness of about 60 nm was formed using 2-TNATA, the hole transport layer 108 was formed using the compounds described above to a thickness of about 30 nm, the emission layer 110 was formed using ADN doped with 3% TBP to a thickness of about 25 nm, the electron transport layer 112 was formed using Alq₃ to a thickness of about 25 nm, the electron injection layer 114 was formed using LiF to a thickness of about 1 nm, and the cathode 116 was formed using A1 to a thickness of about 100 nm.

With respect to the organic EL devices thus manufactured, the emission efficiency and the life were evaluated. The values were measured and evaluated at current density of 10 mA/cm² and half life of 1,000 cd/m², and are shown in Table 1, below.

TABLE 1

| | Emission efficiency (cd/A) | Life (LT50) (h) |
|---|---|---|
| Example 1 | 6.8 | 2,800 |
| Example 2 | 6.5 | 2,500 |
| Comparative Example 1 | 6.5 | 1,900 |
| Comparative Example 2 | 5.8 | 1,500 |
| Comparative Example 3 | 5.3 | 1,200 |

As shown in Table 1, the organic EL devices of Examples 1 and 2 exhibited improved emission efficiency and increased half life, when compared to the organic EL devices of the Comparative Examples, e.g., the device including the compound of Comparative Example 1 (introducing the indolocarbazole moiety at position 2 of the triphenylene moiety via the connecting group). Thus, the realization of the high efficiency and the long life of the organic EL device may be clearly seen when the indolocarbazole moiety is introduced at position 1 of the triphenylene moiety as well as by the combination of constituting elements of the material.

In addition, through using the compound of Example 2, which included a substituent at position 1 of the triphenylene moiety via a connecting group L of a divalent group derived from an aromatic compound not via a single group, the improvement of the emission efficiency and the increase of the half life of the device may be seen.

When a gap between a polycyclic aromatic ring moiety (triphenylene moiety) and an indolocarbazole part is decreased, or a combining type having increasing twist degree, e.g., 1-triphenylenyl group, is introduced, HOMO and LUMO may be separated satisfactorily, and thus, trapping effect of excited energy from an emission layer in the emission layer may be increased.

By way of summation and review, in application of an organic EL device in a display apparatus, the high efficiency and the long life of the organic EL device may be required, and the normalization and the stabilization of a hole transport layer or an emission layer may be considered to realize the high efficiency and the long life of the organic EL device. As a material for a hole transport layer or an emission layer, various compounds, e.g., an anthracene derivative or a carbazole derivative may be used. A material for an organic EL device having high efficiency and long life may include a compound in which 2-triphenylenyl group and a condensed polycyclic N-indolo group via a single bond or a divalent group derived from an aromatic compound. In addition, a condensed polycyclic compound obtained by combining the residual group of a condensed aromatic hydrocarbon compound with a nitrogen atom on the skeleton of an indolocarbazole derivative may be used.

However, the above-described materials for an organic EL device may not exhibit sufficient emission efficiency and emission life, and an organic EL device having higher efficiency and longer emission life may be desired.

The embodiments may provide an organic EL device having high efficiency and long life.

In the material for an organic EL device according to an embodiment, an indolocarbazole moiety having high hole tolerance and a triphenylene moiety having hole tolerance and electron tolerance may be combined via a connecting group, and the hole tolerance and the electron tolerance of the organic EL device may be improved, and the high efficiency and the long life of the organic EL device may be realized. For example, the indolocarbazole moiety and position 1 of the triphenylene moiety may be combined via the connecting group, and a dihedral angle of a molecule may be increased, and the long life of the organic EL device may be realized.

The material for an organic EL device according to an embodiment may include the indolocarbazole moiety, and high hole tolerance may be obtained and thus, the high efficiency and the long life of the organic EL device may be attained.

The organic EL device according to an embodiment may use a single bond or a divalent group described herein as a connecting group, restraining effects of the change of layer quality during driving may be increased, and the increase of driving life may be recognized.

In the material for an organic EL device according to an embodiment, an indolocarbazole moiety having high hole tolerance and a triphenylene moiety having hole tolerance and electron tolerance may be combined via a connecting group, and the hole tolerance and the electron tolerance of the organic EL device may be improved. In addition, by using the material in the emission layer, an organic EL device having high efficiency and long life may be manufactured.

In the material for an organic EL device according to an embodiment, an indolocarbazole moiety having high hole tolerance and a triphenylene moiety having hole tolerance and electron tolerance may be combined via a connecting group, and the hole tolerance and the electron tolerance of the organic EL device may be improved. In addition, by using the material in the layer of stacking layers between the anode and the emission layer, an organic EL device having high efficiency and long life may be manufactured.

According to an embodiment, a material for an organic EL device having high efficiency and long life, and an organic EL device using the same may be provided. For example, a material in an emission layer or a layer of stacking layers between the emission layer and an anode of an organic EL device having high efficiency and long life, and an organic EL device using the same may be provided. According to an embodiment, an indolocarbazole moiety having high hole tolerance and a triphenylene moiety having hole tolerance and electron tolerance may be combined via a connecting group, and the hole tolerance and the electron tolerance of the organic EL device may be improved. In addition, an organic EL device having high efficiency and long life may be manufactured.

The embodiments may provide a material for an organic electroluminescence device that driven at a low driving voltage and having high efficiency and long life in a blue emission region.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A compound for an organic electroluminescence (EL) device, the compound being represented by the following Formula 1: 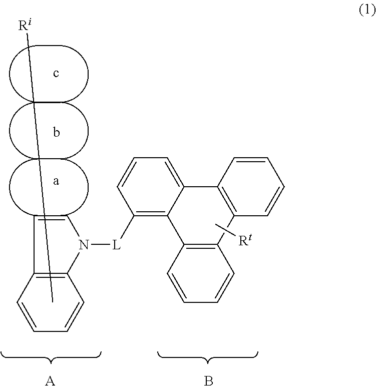
wherein, in Formula 1,
A is an indolocarbazole moiety having 0 to 11 of a group Rⁱ,
B is a triphenylene moiety having 0 to 11 of a group R^{t},
L is a single bond or a divalent group of an aromatic hydrocarbon or aromatic heterocycle having up to 12 ring carbon atoms,
ring a and ring c are each independently an aromatic hydrocarbon ring having 6 ring carbon atoms, and
ring b is a heteroaromatic ring having 4 ring carbon atoms and 1 ring nitrogen atom.

2. The compound for an organic EL device as claimed in claim 1, wherein A in Formula 1 is a monovalent group represented by one of the following Formulae (A1), (A2), (A3), (A4), (A5), or (A6): 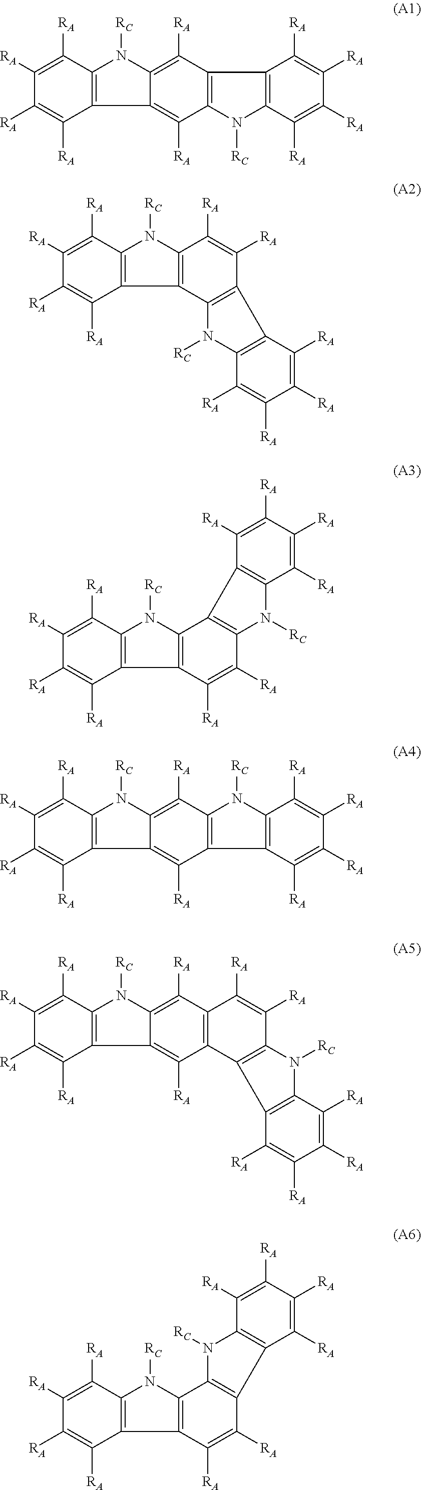
wherein, in Formulae (A1), (A2), (A3), (A4), (A5), and (A6),
R_{A} is a Rⁱ of Formula 1, and each R_{A} is independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, or an alkylamine group or an arylamine group represented by —N(R_{B})R_{B},
each R_{B} is independently a saturated or unsaturated hydrocarbon having 1 to 10 carbon atoms, and
each R_{C} is independently R_{A} or a single bond to L.

3. The compound for an organic EL device as claimed in claim 1, wherein L in Formula 1 is a divalent group represented by one of the following Formulae (L1), (L2), (L3), or (L4): 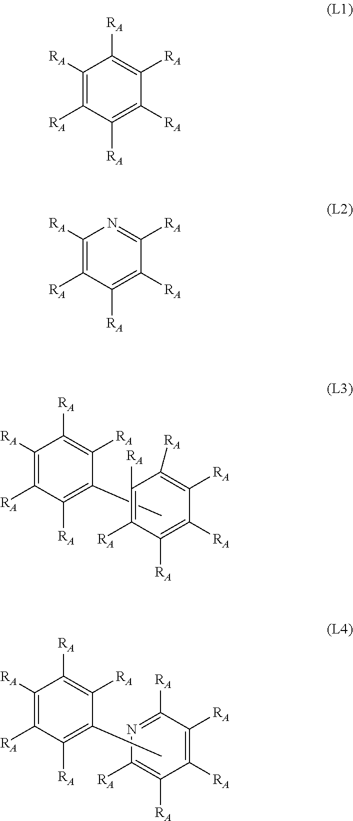
wherein, in Formulae (L1), (L2), (L3), and (L4),
each R_{A} is independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, an alkylamine group or an arylamine group represented by —N(R_{B})R_{B}, or a bond to A or B of Formula 1, and
R_{B} is a saturated or unsaturated hydrocarbon having 1 to 10 carbon atoms.

4. An organic electroluminescence (EL) device comprising a compound for an organic EL device in at least one of an emission layer or a layer stacked between the emission layer and an anode,
the compound for an organic EL device being represented by the following Formula 1: 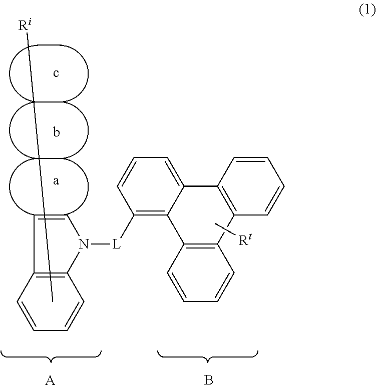
wherein, in Formula 1,
A is an indolocarbazole moiety having 0 to 11 of a group Rⁱ,
B is a triphenylene moiety having 0 to 11 of a group R^{t},
L is a single bond or a divalent group of an aromatic hydrocarbon or aromatic heterocycle having up to 12 ring carbon atoms,
ring a and ring c are each independently an aromatic hydrocarbon ring having 6 ring carbon atoms, and
ring b is a heteroaromatic ring having 4 ring carbon atoms and 1 ring nitrogen atom.

5. The organic EL device as claimed in claim 4, wherein A in Formula 1 is a monovalent group represented by one of the following Formulae (A1), (A2), (A3), (A4), (A5), or (A6): 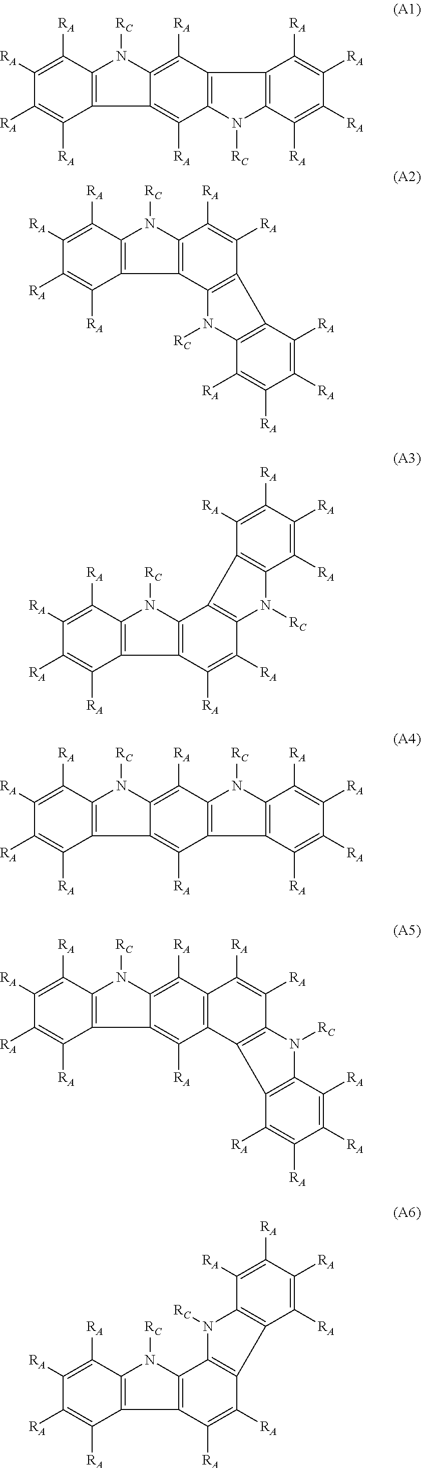
wherein, in Formulae (A1), (A2), (A3), (A4), (A5), and (A6),
R_{A} is a IV of Formula 1, and each R_{A} is independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, or an alkylamine group or an arylamine group represented by —N(R_{B})R_{B}, each R_{B} is independently a saturated or unsaturated hydrocarbon having 1 to 10 carbon atoms, and
each R_{C} is independently R_{A} or a single bond to L.

6. The organic EL device as claimed in claim 4, wherein L in Formula 1 is a divalent group represented by one of the following Formulae (L1), (L2), (L3), or (L4): 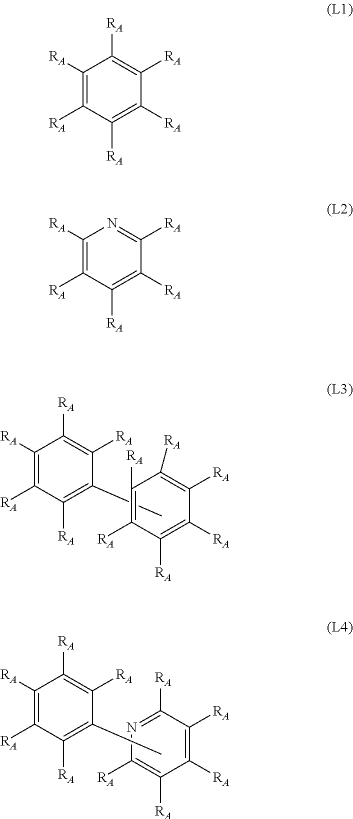
wherein, in Formulae (L1), (L2), (L3), and (L4),
each R_{A} is independently hydrogen, deuterium, a halogen atom, a nitrile group, a saturated or unsaturated hydrocarbon group having 1 to 30 carbon atoms, an alkoxy group represented by —OR_{B}, an alkylthio group represented by —SR_{B}, an alkylamine group or an arylamine group represented by —N(R_{B})R_{B}, or a bond to A or B of Formula 1, and
R_{B} is a saturated or unsaturated hydrocarbon having 1 to 10 carbon atoms.

7. The organic EL device as claimed in claim 4, wherein the compound represented by Formula 1 is one of the following Compounds 1 to 6:

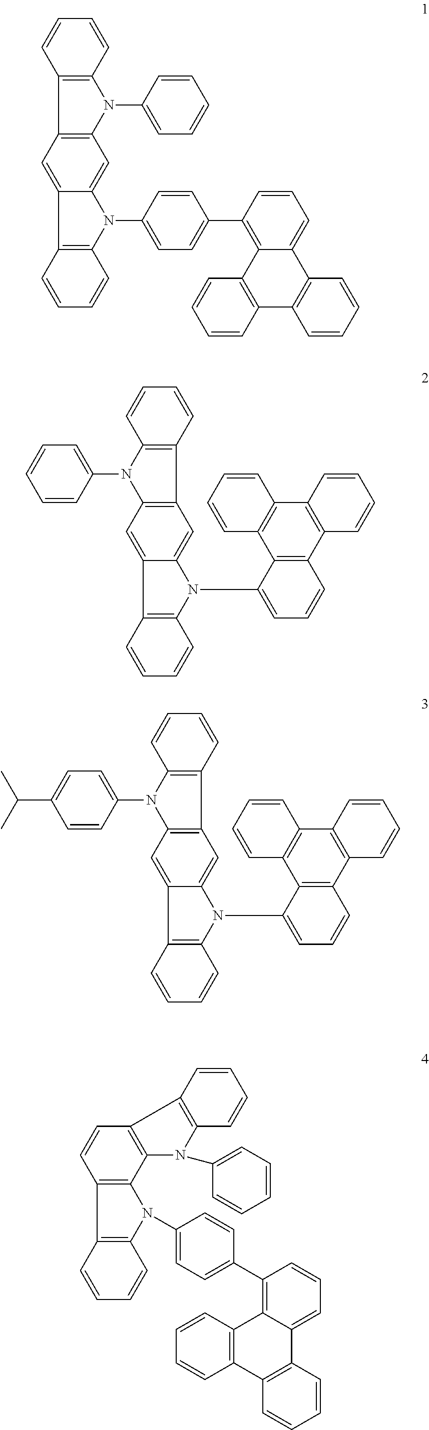

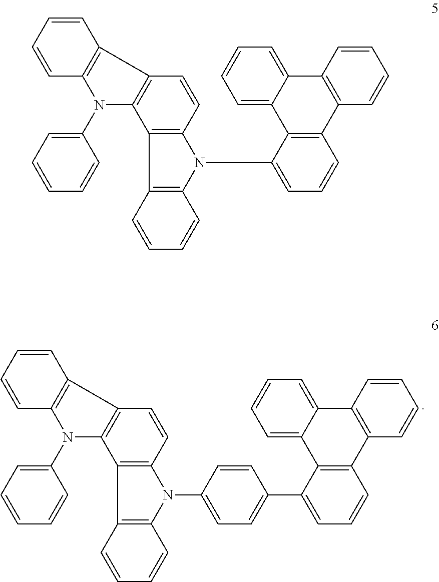 [SMILES: c1ccc(-n2c3ccccc3c3ccc4c(c5ccccc5n4-c4cccc5c6ccccc6c6ccccc6c45)c32)cc1 ; c1ccc(-n2c3ccccc3c3ccc4c(c5ccccc5n4-c4ccc(-c5cccc6c7ccccc7c7ccccc7c56)cc4)c32)cc1]

8. The organic EL device as claimed in claim 4, wherein the compound represented by Formula 1 is one of the following Compounds 7 to 12:

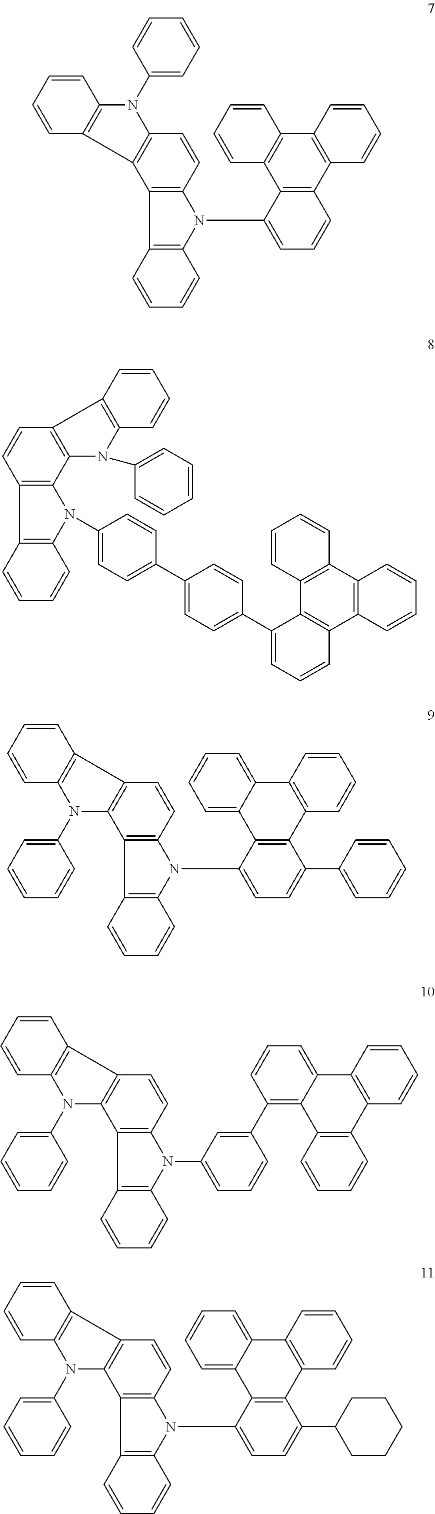 [SMILES: c1ccc(-n2c3ccccc3c3c4c5ccccc5n(-c5cccc6c7ccccc7c7ccccc7c56)c4ccc32)cc1 ; c1ccc(-n2c3ccccc3c3ccc4c5ccccc5n(-c5ccc(-c6ccc(-c7cccc8c9ccccc9c9ccccc9c78)cc6)cc5)c4c32)cc1 ; c1ccc(-c2ccc(-n3c4ccccc4c4c3ccc3c5ccccc5n(-c5ccccc5)c34)c3c4ccccc4c4ccccc4c23)cc1 ; c1ccc(-n2c3ccccc3c3ccc4c(c5ccccc5n4-c4cccc(-c5cccc6c7ccccc7c7ccccc7c56)c4)c32)cc1 ; c1ccc(-n2c3ccccc3c3ccc4c(c5ccccc5n4-c4ccc(C5CCCCC5)c5c6ccccc6c6ccccc6c45)c32)cc1]

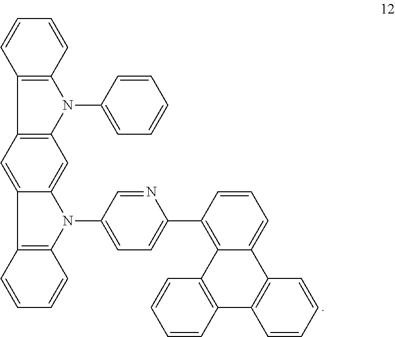 [SMILES: c1ccc(-n2c3ccccc3c3cc4c5ccccc5n(-c5ccc(-c6cccc7c8ccccc8c8ccccc8c67)nc5)c4cc32)cc1]

9. The organic EL device as claimed in claim 4, wherein the compound represented by Formula 1 is one of the following Compounds 13 to 18:

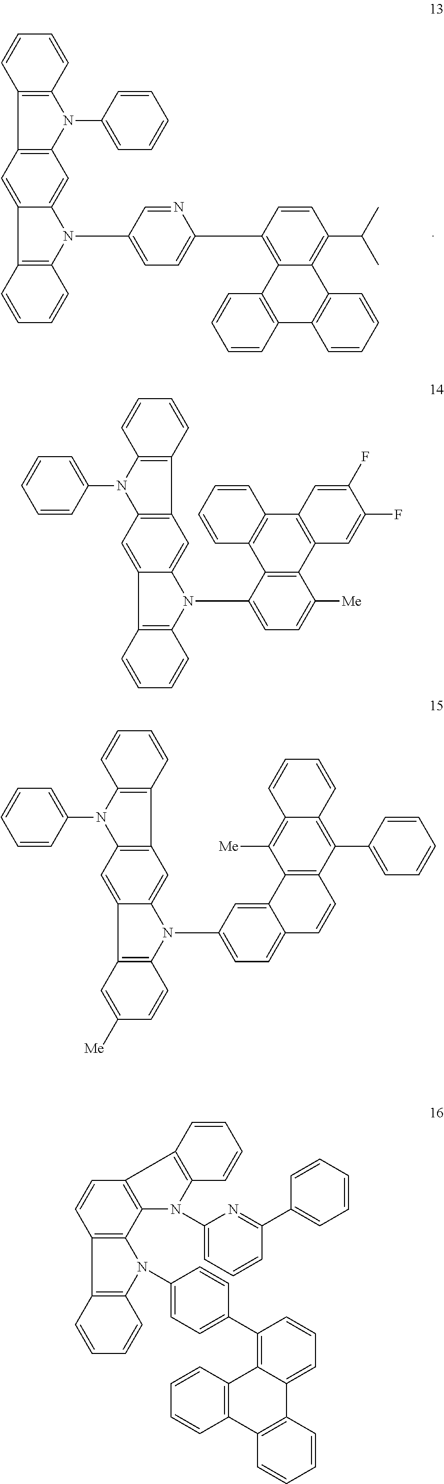

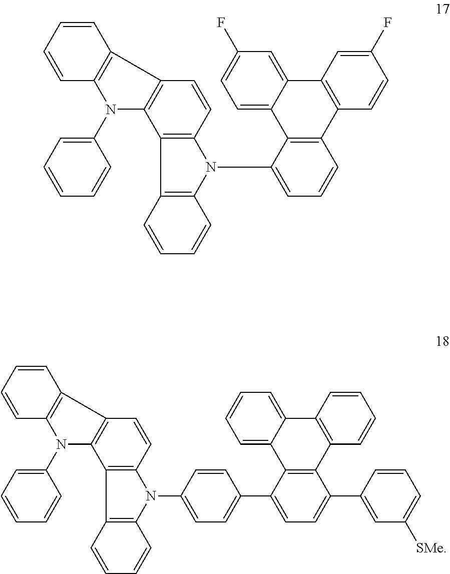 [SMILES: Fc1ccc2c(c1)c1cc(F)ccc1c1c(-n3c4ccccc4c4c3ccc3c5ccccc5n(-c5ccccc5)c34)cccc21 ; CSc1cccc(-c2ccc(-c3ccc(-n4c5ccccc5c5c4ccc4c6ccccc6n(-c6ccccc6)c45)cc3)c3c4ccccc4c4ccccc4c23)c1]

10. The organic EL device as claimed in claim 4, wherein the compound represented by Formula 1 is one of the following Compounds 19 to 24: 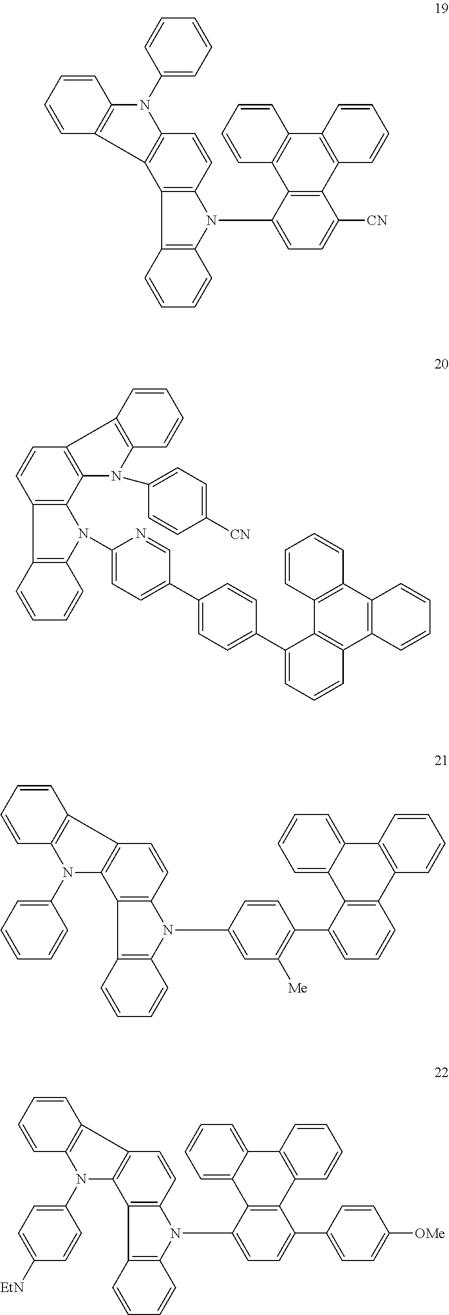 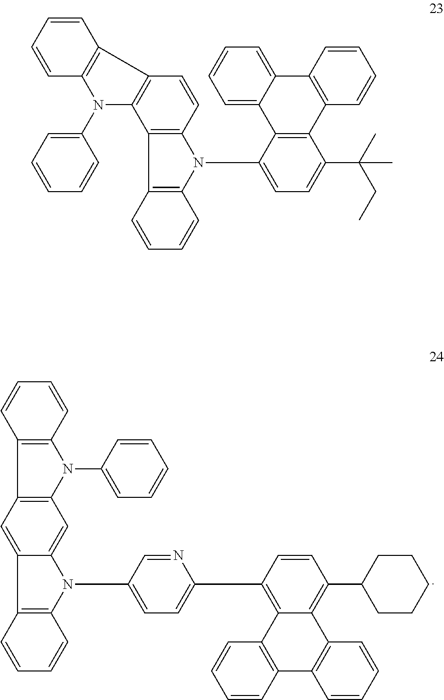 [SMILES: CCC(C)(C)c1ccc(-n2c3ccccc3c3c2ccc2c4ccccc4n(-c4ccccc4)c23)c2c3ccccc3c3ccccc3c12 ; c1ccc(-n2c3ccccc3c3cc4c5ccccc5n(-c5ccc(Cc6ccc(C7CCCCC7)c7c8ccccc8c8ccccc8c67)nc5)c4cc32)cc1]
